(19) United States
(12) Patent Application Publication
(10) Pub. No.: US 2017/0316822 A1
(43) Pub. Date: Nov. 2, 2017

(54) SWITCH DEVICE AND STORAGE UNIT

(71) Applicant: SONY SEMICONDUCTOR SOLUTIONS CORPORATION, Kanagawa (JP)

(72) Inventors: Hiroaki SEI, Kanagawa (JP); Kazuhiro OHBA, Tokyo (JP)

(73) Assignee: Sony Semiconductor Solutions Corporation, Kanagawa (JP)

(21) Appl. No.: 15/512,956

(22) PCT Filed: Sep. 8, 2015
(86) PCT No.: PCT/JP2015/075464

§ 371 Date: Mar. 21, 2017

(30) Foreign Application Priority Data
Sep. 30, 2014 (JP) 2014-201722

(51) Int. Cl. G11C 13/00; H01L 45/00; H01L 27/24

(52) U.S. Cl. CPC G11C 13/0004; H01L 45/145; H01L 45/1246; H01L 45/1233; H01L 45/06; G11C 13/0007; H01L 27/2463; G11C 13/0069; G11C 2013/0078; G11C 2213/34

(57) ABSTRACT

A switch device includes a first electrode, a second electrode, and a switch layer. The second electrode is disposed to face the first electrode. The switch layer is provided between the first electrode and the second electrode. The switch layer contains an amorphous material made of at least germanium (Ge) and one of nitrogen (N) and oxygen (O).

### TECHNICAL FIELD

The disclosure relates to a switch device including a switch layer having switch characteristics between electrodes, and a storage unit including the switch device.

### BACKGROUND ART

In recent years, an increase in capacity has been demanded in a non-volatile memory for data storage. The non-volatile memory for data storage is typified by a resistive random access memory such as a resistance random access memory (ReRAM) and a phase-change random access memory (PRAM). However, the resistive random access memory using an existing access transistor results in an increased floor area per unit cell. Accordingly, as compared, for example, with a flash memory such as a NAND flash memory, it has been difficult to achieve the increase in capacity of a non-volatile memory even in a case where the non-volatile memory is miniaturized using the same design rules. In contrast, when using a so-called cross-point array structure in which memory devices are provided at respective intersections (cross points) of intersecting wiring lines, a floor area per unit cell is reduced, making it possible to achieve the increase in capacity of the non-volatile memory.

A bidirectional memory having the cross-point array structure typically adopts V-V/2 selection system as a method for selecting any memory cell. In this selection system, a voltage V as a selection voltage is applied to a selected memory cell, while 0V or V/2 is applied to other cells. A memory cell to which the V/2 is applied is referred to as a semi-selected cell.

The cross-point memory is able to increase a capacity by increasing the number of memory cells. However, as the number of the memory cells increases, the total amount of current also increases. The current flows into each semi-selected cell to which the V/2 is applied. Therefore, in order to achieve a power-saving cross-point memory having an increased capacity, it is necessary to suppress a maximum current flowing into a circuit. In other words, it is requested to sufficiently secure a selection ratio (ON/OFF ratio) between a large current value (ON) and a small current value (OFF). The large current value is a value of a flowing current at the time when the voltage V is applied to the memory cell (at the time of selection), while the small current value is a value of a flowing current at the time when the V/2 is applied to the memory cell (at the time of semi-selection).

The ON/OFF ratio may be increased by combining memory devices configuring each memory cell with switch devices. Examples of the memory devices may include a so-called nonlinear resistive memory device without a threshold voltage (e.g., metal-insulator-metal (MIM)) and an avalanche diode (see, e.g., NPL 1 and NPL 2). The nonlinear resistive memory device without a threshold voltage is configured by a PN diode or a metal oxide, and has a resistance value that changes continuously with respect to an applied voltage. The avalanche diode has a resistance value that becomes smaller at a certain threshold voltage or higher. Other examples may include a switch device made of a chalcogenide material (ovonic threshold switch (OTS); see, e.g., PTL1 and PTL2).

### CITATION LIST

### Patent Literature

PTL 1: Japanese Unexamined Patent Application Publication No. 2006-86526
PTL 2: Japanese Unexamined Patent Application Publication No. 2010-157316

### Non-Patent Literature

NPL 1: Jiun-Jia Huang et al., 2011, IEEE IEDM 11, pp. 733-736
NPL 2: Wootae Lee et al., 2012, IEEE VLSI Technology symposium, pp. 37-38

### SUMMARY OF INVENTION

Among the above-described switch devices, the ovonic threshold switch and the avalanche diode having a threshold voltage are preferable as a switch device to be combined with the memory device, because the avalanche diode and the ovonic threshold switch are able to easily have a wide selection ratio by setting the voltage V and V/2 applied, respectively, at the time of selection and non-selection (or semi-selection) so as to cover the threshold voltage. While the detail is described later, particularly, the ovonic threshold switch is able to easily have a wider selection ratio, because the ovonic threshold switch has S type negative resistance characteristics or negative resistance characteristics in which a resistance value is decreased and an apparent resistance value becomes minus at a certain threshold voltage or higher.

However, the chalcogenide material forming the ovonic threshold switch has low chemical stability and low thermal stability, thus causing low resistance with respect to a semiconductor process used to achieve a memory having an increased capacity, for example, with respect to a high temperature process or a miniaturization process using etching or other methods.

It is therefore desirable to provide a switch device and a storage unit having stability with respect to a semiconductor process and having large ON/OFF ratio.

A switch device according to an embodiment of the technology includes a first electrode, a second electrode, and a switch layer. The second electrode is disposed to face the first electrode. The switch layer is provided between the first electrode and the second electrode. The switch layer contains an amorphous material made of at least germanium (Ge) and one of nitrogen (N) and oxygen (O).

A storage unit according to an embodiment of the technology is provided with a plurality of memory cells. Each of the plurality of memory cells includes a storage device, and the switch device coupled to the storage device.

In the switch device and the storage unit according to the respective embodiments of the technology, the switch layer provided between the first electrode and the second electrode contains the amorphous material made of at least germanium (Ge) and one of nitrogen (N) and oxygen (O). The material has high affinity to the semiconductor process, and is relatively stable chemically and thermally, thus improving stability for the semiconductor process.

According to the switch device or the storage unit of the embodiment of the technology, the switch layer provided between the first electrode and the second electrode contains an amorphous material made of at least germanium (Ge) and one of nitrogen (N) and oxygen (O). This allows for stability for the semiconductor process as well as an increase in an ON/OFF ratio of a flowing current at the time of voltage application to the memory device. It is to be noted that the effects described herein are not necessarily limitative, and may be any effects described in the present disclosure.

### BRIEF DESCRIPTION OF DRAWINGS

FIG. 1 is a cross-sectional view of a configuration of a switch device according to an embodiment of the disclosure.

FIG. 2A is a characteristic diagram illustrating a characteristic of a current-voltage (I-V) characteristic of a memory device.

FIG. 2B is a characteristic diagram illustrating a change in a voltage of the switch device.

FIG. 2C is a characteristic diagram illustrating an I-V characteristic of a memory cell.

FIG. 3 is a perspective view of an example of a memory cell array including the switch device illustrated in FIG. 1.

FIG. 4 is a cross-sectional view of a configuration of a memory cell illustrated in FIG. 3.

FIG. 5A is a perspective view of another example of the memory cell array illustrated in FIG. 3.

FIG. 5B is a perspective view of another example of the memory cell array illustrated in FIG. 3.

FIG. 5C is a perspective view of another example of the memory cell array illustrated in FIG. 3.

FIG. 5D is a perspective view of another example of the memory cell array illustrated in FIG. 3.

FIG. 5E is a perspective view of another example of the memory cell array illustrated in FIG. 3.

FIG. 5F is a perspective view of another example of the memory cell array illustrated in FIG. 3.

FIG. 6A is a cross-sectional view of an example of a configuration of a switch device according to a modification example of the disclosure.

FIG. 6B is a cross-sectional view of another example of the configuration of the switch device according to the modification example of the disclosure.

FIG. 6C is a cross-sectional view of another example of the configuration of the switch device according to the modification example of the disclosure.

FIG. 7A is a cross-sectional view of an example of a configuration of a memory cell including the switch device illustrated in FIG. 6C.

FIG. 7B is a cross-sectional view of another example of the configuration of the memory cell including the switch device illustrated in FIG. 6C.

FIG. 7C is a cross-sectional view of another example of the configuration of the memory cell including the switch device illustrated in FIG. 6C.

FIG. 8 is an I-V characteristic diagram of Experimental Example 1-1 of the disclosure.

FIG. 9 is an I-V characteristic diagram of Experimental Example 1-2 of the disclosure.

FIG. 10 is an I-V characteristic diagram of Experimental Example 2-2 of the disclosure.

FIG. 11 is an I-V characteristic diagram of Experimental Example 2-4 of the disclosure.

FIG. 12 is an I-V characteristic diagram of Experimental Example 2-12 of the disclosure.

FIG. 13 is an I-V characteristic diagram of Experimental Example 2-13 of the disclosure.

FIG. 14 is a characteristic diagram illustrating a relationship between Si/(Si+Ge) ratio and a threshold voltage.

FIG. 15 is a characteristic diagram illustrating a relationship between a nitrogen content ratio and a threshold voltage in Experiment 3 of the disclosure.

FIG. 16 is a characteristic diagram illustrating a relationship between an oxygen content ratio and a threshold voltage in Experiment 3 of the disclosure.

FIG. 17 is an I-V characteristic diagram of Experimental Example 4-1 of the disclosure.

FIG. 18 is an I-V characteristic diagram of Experimental Example 4-3 of the disclosure.

FIG. 19 is an I-V characteristic diagram of Experimental Example 4-5 of the disclosure.

FIG. 20 is an I-V characteristic diagram of Experimental Example 4-6 of the disclosure.

FIG. 21 is an I-V characteristic diagram of Experimental Example 5-1 of the disclosure.

FIG. 22 is an I-V characteristic diagram of Experimental Example 5-2 of the disclosure.

### DESCRIPTION OF EMBODIMENTS

Some embodiments of the disclosure are described below in the following order with reference to drawings.

1. Embodiment (An example in which a switch layer containing germanium (Ge) and one of nitrogen (N) and oxygen (O) is provided between electrodes)

1-1. Switch Device

1-2. Storage Unit

2. Modification Example (An example in which a high resistive layer is added between electrodes)

### 3. Examples

### 1. Embodiment

### (1-1. Switch Device)

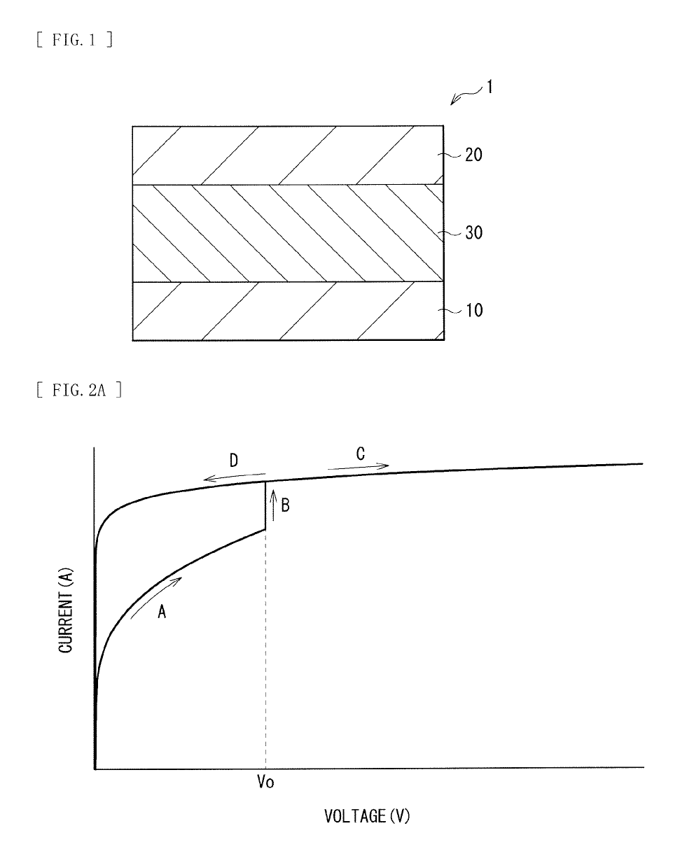

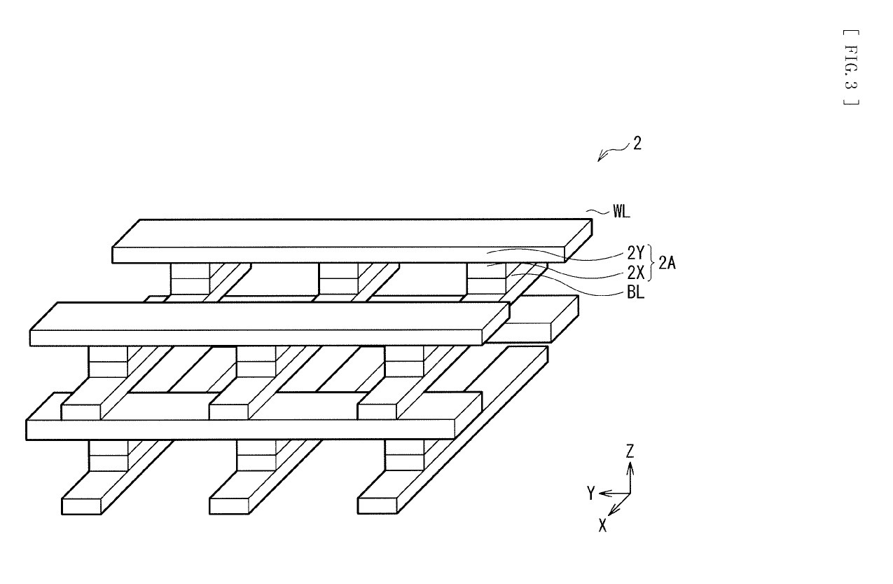

FIG. 1 illustrates a cross-sectional configuration of a switch device 1 according to an embodiment of the disclosure. The switch device 1 is provided for selectively operating any storage device (corresponding to storage device 2Y; illustrated in FIG. 3) among a plurality of storage devices in a memory cell array 2 having a so-called cross-point array structure illustrated in FIG. 3, for example. The switch device 1 (corresponding to switch device 2X; illustrated in FIG. 3) is coupled in series to the storage device 2Y (corresponding specifically to storage layer 40), and includes a lower electrode 10 (corresponding to first electrode), a switch layer 30, and an upper electrode 20 (corresponding to second electrode) in this order.

The lower electrode 10 is made of a wiring material used in a semiconductor process. Examples of the wiring material may include tungsten (W), tungsten nitride (WN), titanium nitride (TiN), copper (Cu), aluminum (Al), molybdenum (Mo), tantalum (Ta), tantalum nitride (TaN), and silicide. When the lower electrode 10 is made of a material, such as Cu, that has a possibility of causing ionic conduction by an electric field, a surface of the lower electrode 10 made of a material such as copper (Cu) may be covered with a material, such as tungsten (W), tungsten nitride (WN), titanium nitride (TiN), or tantalum nitride (TaN), that is less likely to cause ionic conduction and thermal diffusion.

The switch layer 30 according to the present embodiment contains an amorphous material made of germanium (Ge) and one of nitrogen (N) and oxygen (O). Containing nitrogen or oxygen at several percent in the switch layer 30 suffices. More specifically, nitrogen may be preferably contained at equal to or higher than 3 atomic % and at equal to or lower than 40 atomic %, for example. Oxygen may be preferably contained at equal to or higher than 3 atomic % and at equal to or lower than 55 atomic %, for example. This allows the switch layer 30 to have negative resistance characteristics in which an apparent resistance value becomes minus at a certain threshold voltage or higher, causing several orders of current to flow when a voltage applied to the switch device 1 exceeds a certain value (switching threshold voltage).

The switch layer 30 may preferably contain, as an additive element, one of or two or more of boron (B), carbon (C), and silicon (Si) in addition to those described above. The use of these additive elements makes it possible to decrease a current value in an OFF state (OFF current value) and to further increase an ON/OFF ratio of a memory cell. Further, the switch layer 30 may preferably have a film thickness of equal to or less than 50 nm, for example, although the film thickness is not particularly limited.

It is to be noted that the switch layer 30 may contain another element unless the element impair the effects of the disclosure.

A known semiconductor wiring material may be used for the upper electrode 20 similarly to the lower electrode 10; however, a stable material that does not react with the switch layer 30 even after post annealing may be preferable.

The switch device 1 according to the present embodiment has switch characteristics of a high resistance value (high resistance state; OFF state) in an initial state and of a low resistance value (low resistance state; ON state) at a certain voltage (switching threshold voltage) upon application of a voltage. The switch device 1 also has negative resistance characteristics. Further, the switch device 1 returns to the high resistance state, when an applied voltage is lowered below the switching threshold voltage or when the application of the voltage is stopped, and thus the ON state is not maintained. In other words, the switch device 1 does not undergo phase transition (between a non-crystalline phase (an amorphous phase) and a crystalline phase) of the switch layer 30, due to application of a voltage pulse or a current pulse from an unillustrated power supply circuit (a pulse application section) through the lower electrode 10 and the upper electrode 20.

As described above, the increase in the capacity of the memory (memory cell array) may be achieved by adopting the cross-point array structure. In the cross-point array structure, there is disposed the memory cell including a memory device and the switch device being stacked near a cross point between intersecting wiring lines, as illustrated in FIG. 3.

When the memory cell is configured only by the memory device, a value of a current flowing upon application of a semi-selection voltage V/2 to the memory cell is equal to a current value upon application of the voltage of V/2 to the memory device. In other words, low resistance state of the memory device causes a large current (OFF) to flow, thus making it difficult to selectively operate any memory cell in a cross-point memory configured by a plurality of memory cells.

In contrast, when the memory cell is configured by the memory device and the switch device, more specifically when the memory cell is configured by the memory device and the switch device being coupled to each other, the value of a current flowing upon application of the semi-selection voltage V/2 to the memory cell becomes smaller, when the resistance value of the switch device is larger than the resistance value of the memory device. This is because the applied voltage is divided mostly for the switch device; in other words, a leak current (OFF) flowing into a semi-selected cell is reduced. Further, in a case where a selection voltage V is applied to the memory cell, when the selection voltage V is greater than a threshold voltage of the switch device, the resistance value of the switch device is lowered (switched) to allow a current to flow (ON), thus causing a voltage to be applied to the memory device coupled in series. In other words, it becomes possible to change the resistance value of the memory device for performing operations such as writing and erasing. In this manner, the combination of the memory device and the switch device makes it possible to increase a selection ratio (ON/OFF ratio) of the memory cell and to selectively operate any memory cell.

The above-mentioned ovonic threshold switch made of the chalcogenide material has the negative resistance characteristics or S type negative resistance characteristics in which an apparent resistance value becomes minus at a certain threshold voltage (switching threshold voltage) or higher. Therefore, the ovonic threshold switch made of the chalcogenide material has a large ON/OFF ratio, and thus is suitable for a switch device used for a memory including a plurality of memory cells, such as the cross-point memory.

A current-voltage (I-V) characteristics of the switch device having the negative resistance characteristics may be examined by: applying a voltage to the switch device and a load resistance having an already known resistance value; measuring a current at the time when the applied voltage is increased; and subtracting the voltage applied to the load resistance. Typically, as the voltage applied to the switch device is increased, a current value is also increased. In the switch device having negative resistance, however, a voltage is decreased at a certain threshold voltage or higher to the contrary, to a degree that the switch device has a voltage referred to as a holding voltage, following which only a current is increased, thus causing an apparent resistance value to be minus. The negative resistance characteristics may also be observed by measuring a voltage at the time when a value of a current to the switch device is increased.

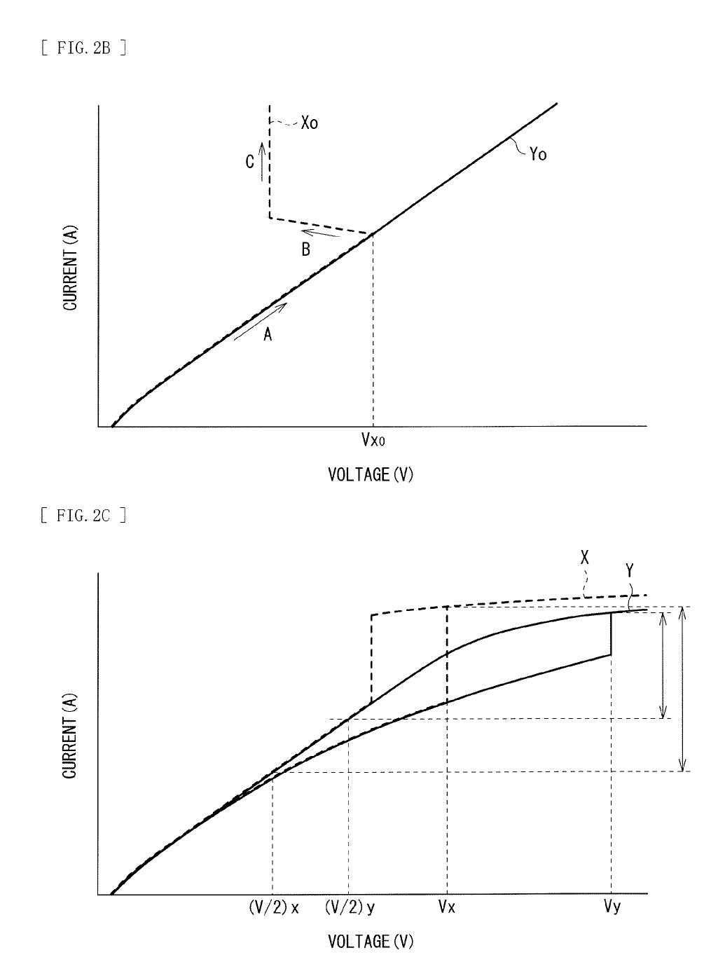

FIG. 2A illustrates an I-V characteristic of a typical memory device. When a voltage applied to the memory device is increased, the memory device changes from an OFF state (A) in which the resistance value is high to a low resistance state (B) at a time period when the voltage reaches a threshold voltage (V₀), bringing the memory device into an ON state (C). Further, when a current to be applied is decreased, the voltage is decreased (D) while maintaining the ON state for the resistance value. In this manner, the memory device has hysteresis characteristics in which a changed resistance value is held even when an applied voltage is lowered. FIG. 2B illustrates a change in a voltage to be applied when a current is changed which is applied to a switch device (X₀) having the negative resistance characteristics and a switch device (Y₀) not having the negative resistance characteristics. It is to be noted that the vertical axis indicates a current value using logarithm. When the current applied to the switch device not having the negative resistance characteristics is increased, the voltage increases monotonously as indicated by Y₀. In contrast, when a current applied to the switch device having the negative resistance characteristics is increased, the voltage increases monotonously (A) up to a threshold voltage (Vx₀); however, the voltage value decreases (B) beyond the threshold voltage (Vx₀), and an apparent resistance value becomes minus. Thereafter, the voltage remains constant (C) even when the current value is increased. It is to be noted that the switch device does not have the hysteresis characteristics regardless of whether the switch device has the negative resistance characteristics.

FIG. 2C illustrates an I-V characteristic of a memory cell (X, Y) in which the memory device having the I-V characteristics illustrated in FIG. 2A is coupled in series to the switch devices (X₀, Y₀) having the characteristics illustrated in FIG. 2B. As illustrated in FIG. 2C, in the memory cell in which the memory device and the switch device are combined together, a steep current increase is observed when the applied voltage reaches a certain voltage (threshold voltage). The steep current increase is generated when the memory device changes from the high resistance state to the low resistance state. A voltage at which the steep voltage change is generated is the switching threshold voltage of the memory cell. In a case where the switching threshold voltages of the memory cells are set as selection operation voltages V (Vx, Vy; ON) and halves of the voltages are set as semi-selection voltages V/2 ((V/2)x, (V/2)y; OFF), when current values (differences between ON and OFF) in this case are compared, it is appreciated that a memory cell (X) configured using the switch device having the negative resistance characteristics has a larger ON/OFF ratio than a memory cell (Y) configured using the switch device not having the negative resistance characteristics. This is because application, to the switch device, of a voltage of equal to or higher than the threshold voltage of the switch device decreases a value of a voltage applied to the switch device due to its negative resistance characteristics, thus increasing a partial pressure applied to the memory device by the decrease in the voltage value. In other words, it is possible to switch the memory cell with a smaller applied voltage V. In addition, it is possible to decrease a leak current at the time of semi-selection of the memory cell because the semi-selection voltage V/2 becomes also smaller.

In this manner, it becomes possible for the switch device having the negative resistance characteristics to improve the ON/OFF ratio of the memory cell, compared to the switch device not having the negative resistance characteristics. It is also possible to reduce a leak current flowing into a non-selected (or semi-selected) memory cell. Therefore, the switch device having the negative resistance characteristics is suitable for a switch device of a memory including a plurality of memory cells, such as the cross-point memory. By further increasing the number of memory cells, it becomes possible to achieve the increase in capacity.

However, the switch device having the negative resistance characteristics made of the chalcogenide material has an issue of low resistance with respect to a semiconductor process used to manufacture memories such as the cross-point memories. More specifically, there are concerns that low chemical stability may cause damage during a miniaturization process by means of operations such as etching and that a relatively low melting point may harm stability of a condition of a high-temperature process.

In contrast, in the switch device 1 according to the present embodiment, the switch layer 30 contains an amorphous material made of germanium (Ge) and one of nitrogen (N) and oxygen (O). The amorphous material containing germanium (Ge) and one of nitrogen (N) and oxygen (O) has high affinity to the semiconductor process, and is relatively stable chemically and thermally. Thus, it becomes possible to easily use the switch device 1 in the miniaturization process by means of operations such as etching as well as in the high-temperature process.

As described above, according to the present embodiment, the switch layer 30 contains an amorphous material made of germanium (Ge) and one of nitrogen (N) and oxygen (O) and thus having high affinity to the semiconductor process. This makes it possible to improve chemical stability and thermal stability with respect to the semiconductor process used for the manufacturing, thus improving reliability. Thus, it becomes possible to provide a storage unit having increased capacity and high reliability.

### (1-2. Storage Unit)

A storage unit (memory) may be configured by, for example, a line or matrix arrangement of a large number of storage devices 2Y described later. In this case, the switch device 1 of the present disclosure, as the switch device 2X, is coupled in series to the storage device 2Y, thus configuring a memory cell 2A. The memory cell 2A is coupled to a sense amplifier, an address decoder, a writing-erasing-reading circuit, and any other component through a wiring line.

FIG. 3 illustrates an example of a so-called cross-point array storage unit (a memory cell array 2) in which the memory cells 2A are disposed at respective intersections (cross points) of intersecting wiring lines. In the memory cell array 2, wiring lines (e.g., bit lines BL (row lines)) and wiring lines (e.g., word lines WL (vertical lines)) are so provided as to intersect with each other for each of the memory cells 2A. The wiring lines (e.g., bit lines BL (row lines)) extends in a Y-axis direction and corresponds to the lower electrode 10. The wiring lines (e.g., word lines WL (vertical lines)) extends in an X-axis direction and corresponds to the upper electrode 20. In this manner, use of the cross-point array structure makes it possible to reduce a floor area per unit cell and to achieve an increase in capacity. Further, by adopting a three-dimensional stereoscopic structure having unit structures being stacked in a Z-axis direction, each of which structures is configured by a bit line, the memory cell 2A, and a word line, it becomes possible to achieve a memory having higher density and having increased capacity. It is to be noted that a structure may also be adopted in which a bit line or a word line is shared by upper and lower memory cells. Further, an unillustrated interlayer insulating film may also be provided between stacked layers of the unit structures each configured by the bit line, the memory cell 2A, and the word line.

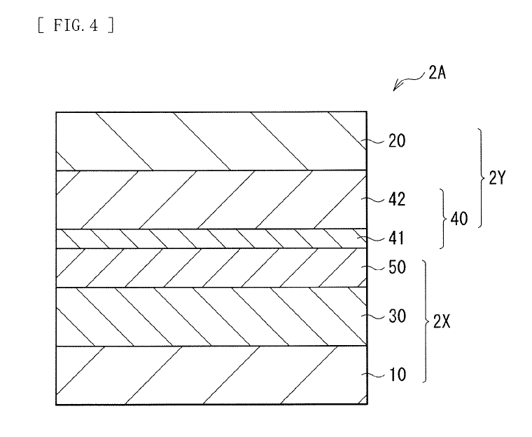

The storage device 2Y configuring the memory cell 2A may include, for example, a lower electrode, a storage layer 40, and an upper electrode in this order. The storage layer 40 may be configured, for example, by a layered structure in which a resistance-change layer 42 and an ion source layer 41 are stacked from the lower electrode side, or a monolayer structure of the resistance-change layer 42. It is to be noted that an intermediate electrode 50 (a third electrode) is provided between the switch layer 30 and the storage layer 40 in this example, and the intermediate electrode 50 serves as both an upper electrode of the switch device 2X and a lower electrode of the storage device 2Y. More specifically, for example, the memory cell 2A may have a configuration in which the switch layer 30, the intermediate electrode 50, the resistance-change layer 42, and the ion source layer 41 are stacked in this order between the lower electrode 10 and the upper electrode 20 as illustrated in FIG. 4.

It is to be noted that the lower electrode 10 and the upper electrode 20 in the memory cell array 2 may be, respectively, the bit line (BL) or the word line (WL) as described above. Alternatively, the lower electrode 10 and the upper electrode 20 may also be so provided as to be interposed by the bit line (BL) and the word line (WL). More specifically, the switch device 2X and the storage device 2Y illustrated in FIG. 3 correspond, respectively, to the switch layer 30 and the storage layer 40. Further, the intermediate electrode 50 is omitted in FIG. 3.

It is sufficient for the storage layer 40 to be, for example, a so-called resistance-change storage device (memory device) having a configuration such as the layered structure of the ion source layer 41 and the resistance-change layer 42 as described above. For example, a resistive random access memory made of a transition metal oxide, a phase-change memory (PCM), or a magnetoresistive random access memory (MRAM) may also be used.

The ion source layer 41 includes a mobile element forming a transmission path in the resistance-change layer 42 by application of an electric field, and, for example, transition metal elements (elements of Groups 4 to 6 of the periodic table), and chalcogen elements. Therefore, the ion source layer 41 has high chemical stability and high heat resistance. Examples of the mobile element may include transition metal elements such as copper (Cu), and aluminum (Al). Other than those elements described above, manganese (Mn), cobalt (Co), iron (Fe), nickel (Ni), platinum (Pt), and silicon (Si), as well as oxygen (O) and nitrogen (N) may also be contained.

The resistance-change layer 42 may be made of, for example, an oxide or a nitride of one of a metal element and a non-metal element, and changes its resistance value upon application of a predetermined voltage between the lower electrode 10 and the upper electrode 20. More specifically, when a voltage is applied between the lower electrode 10 and the upper electrode 20, the transition metal element contained in the ion source layer 41 is moved into the resistance-change layer 42 to form a transmission path, thereby reducing the resistance of the resistance-change layer 42. Alternatively, a structural defect such as an oxygen defect or a nitrogen defect occurs in the resistance-change layer 42 to form a transmission path, thereby reducing the resistance of the resistance-change layer 42. Further, when a voltage in a reverse direction is applied, the transmission path is disconnected or electric conductivity changes, thereby increasing the resistance of the resistance-change layer 42.

It is to be noted that all of the metal elements and the non-metal elements contained in the resistance-change layer 42 may not be necessarily in an oxide state, and some of them may be oxidized. Further, it is sufficient for an initial resistance value of the resistance-change layer 42 to achieve a device resistance of about several MΩ to about several hundreds of GΩ, for example. Although an optimum value of the resistance-change layer 42 changes depending on the size of the device and the resistance value of the ion source layer 41, a film thickness of the resistance-change layer 42 may be preferably within a range of about 1 nm to about 10 nm both inclusive, for example.

A material for the intermediate electrode 50 is not particularly limited as long as the material is, for example, an inert material that is less likely to cause an oxidation-reduction reaction such as ions being dissolved or precipitated into the switch layer 30 and the ion source layer 41 both containing chalcogenide or to cause movement of ions by application of an electric field. It is to be noted that the intermediate electrode 50 may not be necessarily provided, and may be omitted where appropriate.

The storage device 2Y is a resistance-change storage device that changes electrical characteristics (resistance value) of the storage layer 40 upon application of a voltage pulse or a current pulse from an unillustrated power supply circuit (pulse application section) through the lower electrode 10 and the upper electrode 20. In this manner, the storage device 2Y performs writing, erasing, and reading of information.

More specifically, in the storage device 2Y, when a voltage or a current pulse in a “positive direction” (e.g., a negative potential on the first electrode side and a positive potential on the second electrode side) is applied to the device in an initial state (high resistance state), an oxygen defect occurs in the resistance-change layer by ionizing metal elements (e.g., transition metal elements) contained in the ion source layer to disperse the ionized metal elements into the storage layer (e.g., into the resistance-change layer) or by moving oxygen ions. Accordingly, a low-resistance section (transmission path) in a low oxidization state is formed in the storage layer, and the resistance of the resistance-change layer is reduced (a storage state). When a voltage pulse is applied to the device in the low resistance state in a “negative direction” (e.g., a positive potential on the first electrode side and a negative potential on the second electrode side), metal ions in the resistance-change layer are moved into the ion source layer, or oxygen ions are moved from the ion source layer to reduce the oxygen defect of the transmission path portion. This allows the transmission path containing the metal elements to disappear to bring the resistance of the resistance-change layer into a high resistance state (the initial state or an erasing state). It is to be noted that, in a case where the storage layer 40 is configured by a single layer of the resistance-change layer 42, a defect occurs by an electric field applied to the resistance-change layer 42 upon application of a voltage (or a current pulse) in the positive direction, and the defect is repaired by the movement of oxygen ions or nitrogen ions in the resistance-change layer upon application of a voltage pulse in the negative direction.

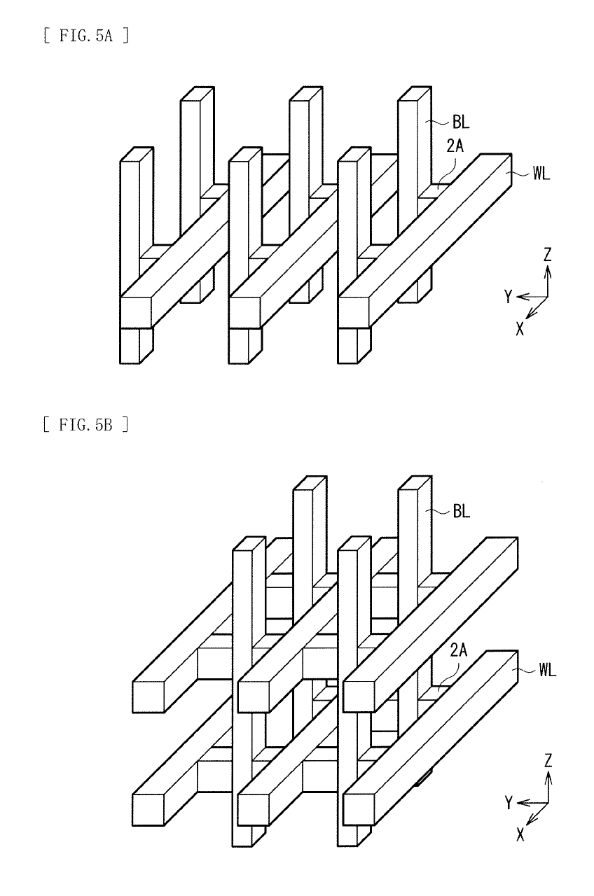

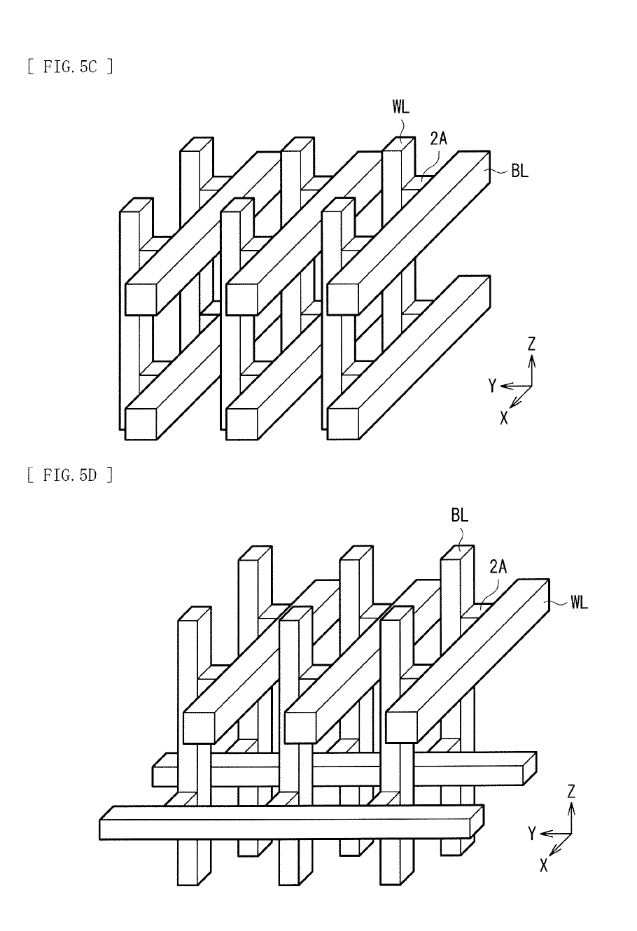

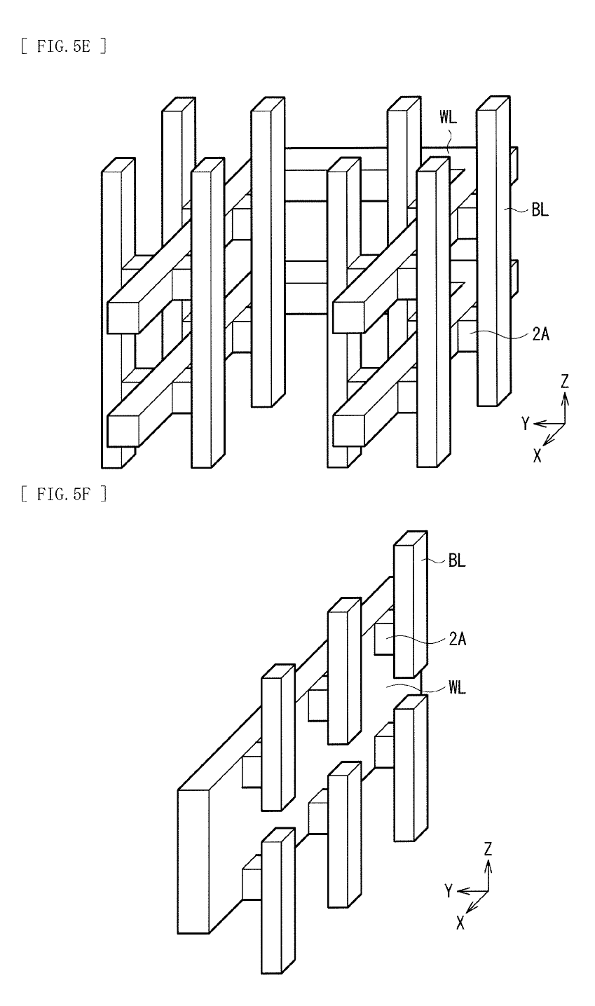

It is to be noted that the cross-point array memory cell array 2 is not limited to the structure illustrated in FIG. 3. For example, a structure illustrated in FIG. 5A may also be adopted in which the WL extends in the X-axis direction and the BL extends in the Z-axis direction while paired WL and BL have the memory cell 2A at an intersection where the WL and the BL face each other. Further, a structure illustrated in FIG. 5B may also be adopted in which the WL and the BL that extend, respectively, in the X-axis direction and in the Z-axis direction have the memory cells 2A at respective both sides of an intersection of the WL and the BL. Furthermore, BL may extend in the X-axis direction while the WL may extend in the Z-axis direction as illustrated in FIG. 5C. Moreover, the WL and the BL may not necessarily extend in a single direction; for example, a structure illustrated in FIG. 5D may also be adopted in which a portion of the WL extends in the X-axis direction or in the Y-axis direction. Alternatively, the WL may be bent continuously from the X-direction to the Y-axis direction as illustrated in FIG. 5E. Moreover, the WL may also be shared by a plurality of BLs as illustrated in FIG. 5F.

It is to be noted that the description has been given of the storage unit (memory cell array 2) according to the present embodiment, by adopting, as an example, the memory unit using the resistance-change storage device 2Y. However, this is not limitative, and the storage unit of the present embodiment may be applied to various memory units. For example, it is possible to apply the storage unit of the present embodiment to any memory configuration such as a programmable read-only memory (PROM) enabling writing only once, an electrically erasable programmable read-only memory (EEPROM) enabling electrical erasing, and a so-called random access memory (RAM) enabling high-speed writing/erasing/reproduction.

### 2. Modification Example

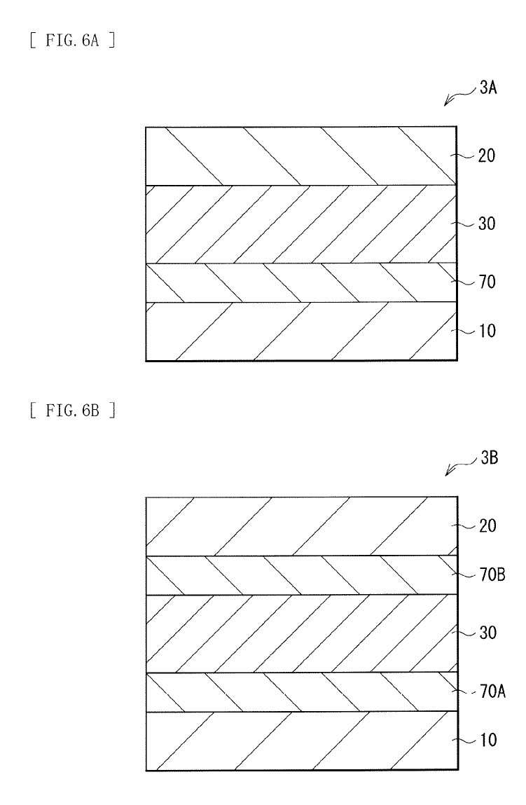

FIG. 6A illustrates an example of a cross-sectional configuration of a switch device 3A as a modification example of the present disclosure according to the foregoing embodiment. The switch device 3A differs from the switch device 1 in that a high resistive layer 70 is provided in addition to the switch layer 30 between the lower electrode 10 and the upper electrode 20. It is to be noted that the same reference numeral is assigned to the same component in the foregoing embodiment, and description therefor is omitted.

The high resistive layer 70, for example, may have a higher insulation property than that of the switch layer 30, and may be made of, for example, an oxide or a nitride of one of a metal element and a non-metal element, or a mixture thereof.

It is to be noted that, in the switch device 3 in the present modification example, it is sufficient for the switch layer 30 and the high resistive layer 70 to be in contact with each other. In this example, the high resistive layer 70 is disposed on the switch layer 30 on the lower electrode 10 side; however, this is not limitative. The high resistive layer 70 may also be provided on the switch layer 30 on the upper electrode 20 side. Further, for example, the high resistive layer 70 may also be provided on the switch layer 30 both on the lower electrode 10 side and the upper electrode 20 side; in other words, the switch layer 30 may be interposed between the high resistive layers 70A and 70B, as illustrated in FIG. 6B. Alternatively, the switch layer 30 may be provided as two layers (switch layers 30A and 30B) to provide the high resistive layer 70 between the switch layer 30A and the switch layer 30B. Furthermore, although not illustrated herein, a multilayer structure may also be adopted in which a plurality of sets of switch layers and a plurality of sets of high resistive layers 70 are stacked.

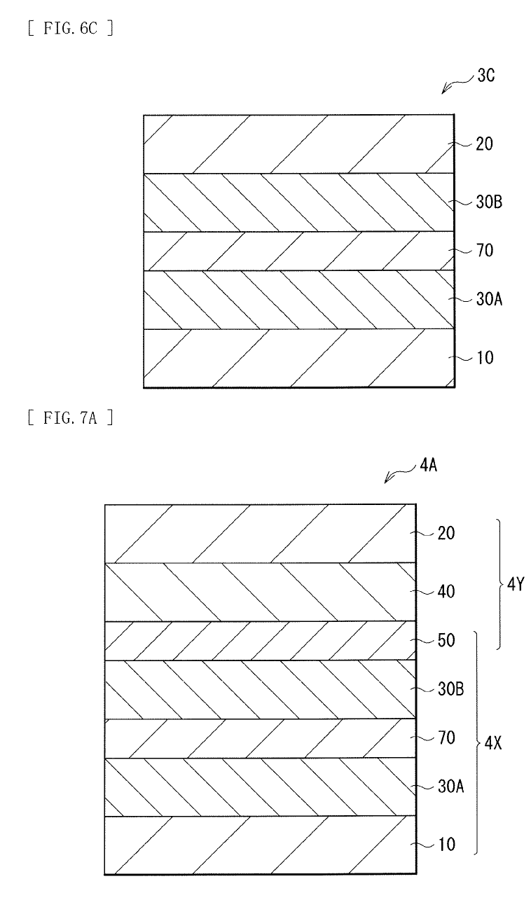

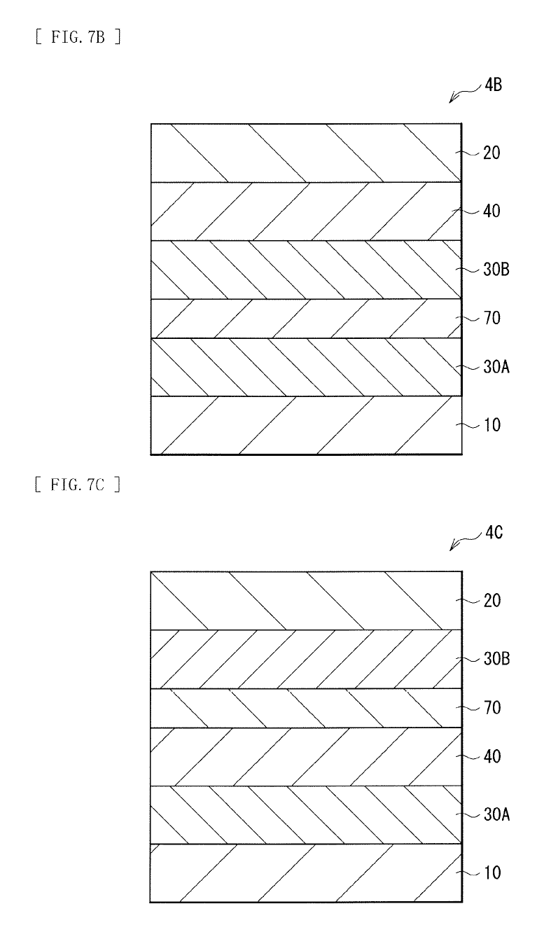

In the memory cell array 2 having the cross-point array structure, examples of a memory cell 4 that couples the switch devices 3A to 3C in the present modification example to the storage device 2Y may include a layered structure illustrated in FIGS. 7A to 7C. Here, FIGS. 7A to 7C illustrate the memory cells 4 configured using the switch device 3C illustrated in FIG. 6C. The memory cell 4A illustrated in FIG. 7A has a configuration in which the storage layer 40 is stacked on the switch layer 30B on the upper electrode side with the intermediate electrode 50 being interposed therebetween. The memory cell 4B illustrated in FIG. 7B removes the intermediate electrode 50. The memory cell 4C illustrated in FIG. 7C has the storage layer provided between the switch layer 30A and the high resistive layer 70. As illustrated, when coupling the switch device 3 to the storage device 2Y in series, the order in which the switch layer 30 (switch layers 30A and 30B), the high resistive layer 70, and the storage layer 40 are stacked is not particularly designated.

It is to be noted that the same holds true for the storage unit in the present modification example also in the case of applying the so-called PCM and MRAM configurations to the storage layer 40.

### 3. Examples

Description is given below of specific Examples of the present disclosure.

### (Experiment 1)

First, the lower electrode 10 made of titanium nitride (TiN) was cleaned by means of reverse sputtering. Next, the switch layer 30 made of germanium containing nitrogen (Ge—Nx) having a film thickness of 20 nm was formed on TiN by means of reactive sputtering while allowing nitrogen to flow into a film-forming chamber, following which tungsten (W) having a film thickness of 30 nm was formed to serve as the upper electrode 20. Thereafter, a heat treatment at 320° C. for 2 hours and a pattering were performed, and then fixed resistances were coupled in series to thereby fabricate a switch device (Experimental Example 1-1, 1 Resistance to 1 Selector Device) for measurement of characteristics. Further, a switch device (Experimental Example 1-2) for measurement of characteristics including the switch layer 30 made of germanium containing oxygen (Ge-Ox) was fabricated using the similar method except allowing oxygen to flow into the film-forming chamber. Compositions of the respective layers of Experimental Examples 1-1 and 1-2 are shown below in the order of “lower electrode/switch layer/upper electrode”. Experimental Examples 1-1 and 1-2 were subjected to DC loop measurement in which an applied voltage Vin was changed as 0V→6V→0V→6V→0V to examine current change (resistance change) with respect to a voltage of only the switch device.

(Experimental Example 1-1) TiN/Ge—Nx (20 nm)/W (30 nm)
(Experimental Example 1-2) TiN/Ge-Ox (30 nm)/W (30 nm)

FIGS. 8 and 9 illustrate a relationship (I-V characteristic) between an applied voltage in Experimental Examples 1-1 and 1-2 and a value of a current flowing into each electrode. The horizontal axis indicates voltage Vsel applied to only a switch device for measurement of characteristics. In other words, the horizontal axis indicates a value obtained by subtracting, from an applied voltage Vin, a voltage applied to a serial resistance. The vertical axis indicates a current value measured in each voltage Vsel. It is to be noted that, in this measurement, the applied voltage Vin is divided mainly into the switch layer 30 and the serial resistance.

As appreciated from FIG. 8, in Experimental Example 1-1 provided with the switch layer 30 made of Ge—Nx, a larger amount of current flows at around 1.5 V. This is because the resistance value of the switch layer 30 is switched from a high resistance state to a low resistance state at around 1.5 V. The voltage at which the resistance value changes is referred to as the switching threshold voltage. In other words, it is appreciated that the switch layer 30 made of Ge—Nx has switch characteristics in which a resistance value is lowered at equal to or higher than the switching threshold voltage to allow a large amount of current to flow. It is also appreciated that the switch layer 30 made of Ge—Nx has negative resistance characteristics because the Vsel applied to the switch device is lowered to the contrary across the threshold voltage. Further, it is appreciated, from this I-V curve, that the ON state where a large amount of current flows is not maintained, and there is no hysteresis in Experimental Example 1-1. Furthermore, it is appreciated that the switch layer 30 made of Ge—Nx has symmetry characteristics also for applied voltage on the minus side. It is appreciated, from FIG. 9, that the switch layer 30 made of Ge-Ox also has these characteristics in Experimental Example 1-2. In other words, it is appreciated that the switch device 1 including the switch layer 30 made of a combined material of germanium and nitrogen or germanium and oxygen has the negative resistance characteristics and the switch characteristics.

### (Experiment 2)

Next, a method similar to that of Experiment 1 was used except that the switch layer 30 was made of SiGe—Nx and that flow rates and compositions of gases flowing at the time of film-formation were changed, to fabricate the following samples (Experimental Examples 2-1 to 2-13). The flow rates and the compositions of the gases in each of the samples were set such that: argon (Ar) gas flow rate was 75 sccm; nitrogen (N₂) flow rate was 10 sccm; and percentage of Si to (Si+Ge) (Si/(Si+Ge)) was set to 0%, 7%, 13%, 20%, 25%, 49%, 59%, 69%, 78%, 85%, 90%, 97%, and 100% for the respective samples. It is to be noted that the compositions of the respective layers of each of Experimental Examples 2-1 to 2-13 are shown below in the order of “lower electrode/switch layer/upper electrode”. Further, each of the thicknesses of the switch layer 30 and the upper electrode 20 in each of the samples was 30 nm. These samples were subjected to the DC loop measurement similarly to Experiment 1 to examine a current change (resistance change) with respect to a voltage.

### (Experimental Example 2-1) TiN/Ge—Nx/W

### (Experimental Example 2-2) TiN/Si7-Ge93-Nx/W

### (Experimental Example 2-3) TiN/Si13-Ge87-Nx/W

### (Experimental Example 2-4) TiN/Si20-Ge80-Nx/W

### (Experimental Example 2-5) TiN/Si25-Ge75-Nx/W

### (Experimental Example 2-6) TiN/Si49-Ge51-Nx/W

### (Experimental Example 2-7) TiN/Si59-Ge41-Nx/W

### (Experimental Example 2-8) TiN/Si69-Ge31-Nx/W

### (Experimental Example 2-9) TiN/Si78-Ge22-Nx/W

### (Experimental Example 2-10) TiN/Si85-Ge15-Nx/W

### (Experimental Example 2-11) TiN/Si90-Ge10-Nx/W

### (Experimental Example 2-12) TiN/Si97-Ge3-Nx/W

### (Experimental Example 2-13) TiN/Si-Nx/W

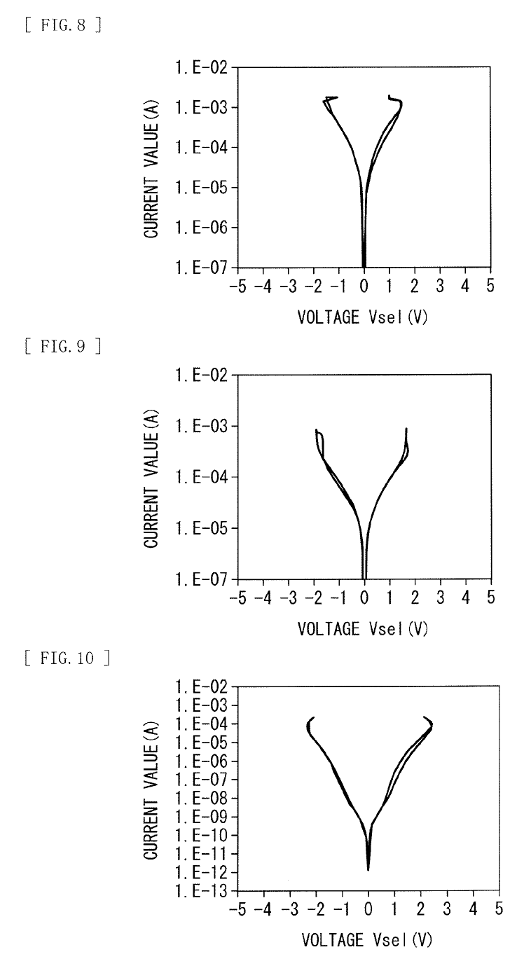

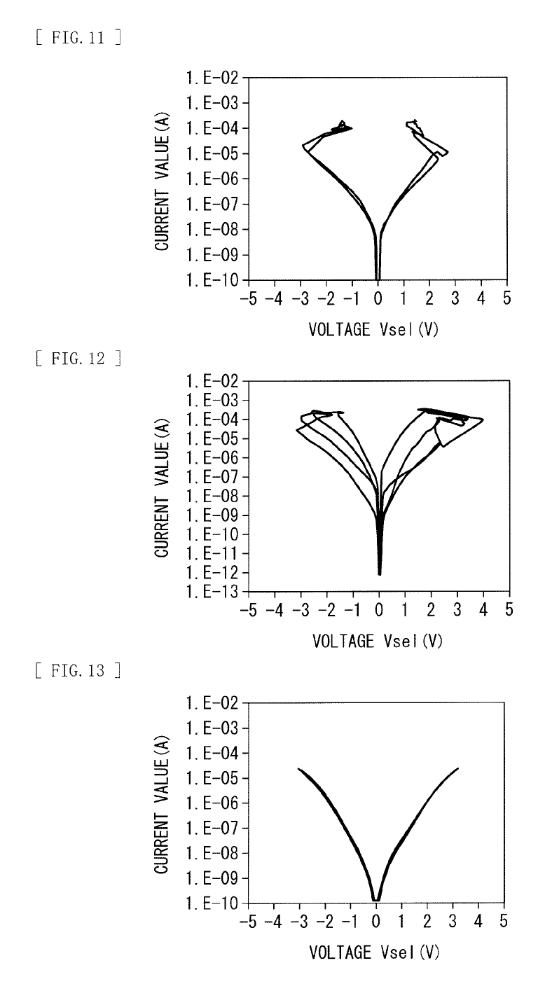

FIGS. 10 to 13 illustrate I-V characteristics of Experimental Examples 2-2, 2-6, 2-11, and 2-13, respectively. It is appreciated, from FIG. 13, that it is not possible to obtain the switch characteristics when configuring the switch layer 30 only by Si-Nx. In contrast, it is appreciated, from FIGS. 10 and 11, that addition of Si to the switch layer 30 made of Ge—Nx allows for decrease in the OFF current value as well as increase in difference with respect to the current value after the switching in comparison with FIG. 9, thus making the resistance change more definite. In other words, it is appreciated that the addition of not only Ge—Nx but also silicon (Si) to the switch layer 30 enables the switch characteristics to be enhanced.

Further, it is appreciated, from FIG. 12, that, when the switch layer 30 contains Si at equal to or higher than 90 atomic % and at equal to or lower than 97 atomic % relative to Si+Ge, it is difficult to use the switch layer 30 repeatedly because the switch layer 30 has a large difference in the current value between times of voltage increase and voltage decrease due to deterioration, although the switch layer 30 has the switch characteristics. Further, as illustrated in FIG. 13, no switch characteristic was shown in Experimental Example 2-13 where the ratio of Si is 100%. It is contemplated, from these results, that a large ratio of Si is likely cause the switch characteristics to be unstable and is likely to cause dispersion. Further, it is appreciated, from FIG. 10 or other drawings, that, in Experimental Examples 2-1 and 2-2 where the ratio of Si is equal to or higher than 0% and equal to or lower than 7%, the switch characteristics are obtained, but a voltage change due to the switch characteristics is small, and a leak current during the OFF state is relatively large.

FIG. 14 illustrates the switching threshold voltage plotted relative to the Si/(Si+Ge) ratio in Experimental Examples 2-1 to 2-13. It is to be noted that the switching threshold voltage in the case of not having the switch characteristics is set to 0. It is appreciated, from FIG. 14, that the switch layer 30 has the switching threshold voltage, the negative resistance characteristics, and the switch characteristics when Si is added to the switch layer 30 within a range of 0% to 97% both inclusive relative to Si+Ge. In other words, it is appreciated that an Si-Nx film containing Ge at a content of equal to or higher than 3% has the negative resistance characteristics and the switch characteristics. That is, the switch device 1 including the switch layer 30 made of silicon, germanium, and nitrogen achieves the negative resistance characteristics and the switch characteristics when the content of Si relative to Si+Ge is equal to or higher than 0% and equal to or lower than 97%; more preferably, the content of Si relative to Si+Ge may be equal to or higher than 7% and equal to or lower than 90%. Putting it in another words with a ratio of Ge, it may be said that the negative resistance characteristics and the switch characteristics are achieved when the percentage of Ge relative to Ge+Si is equal to or higher than 3% and equal to or lower than 100%; more preferably, the percentage of Ge may be equal to or higher than 10% and equal to or lower than 93%.

### (Experiment 3)

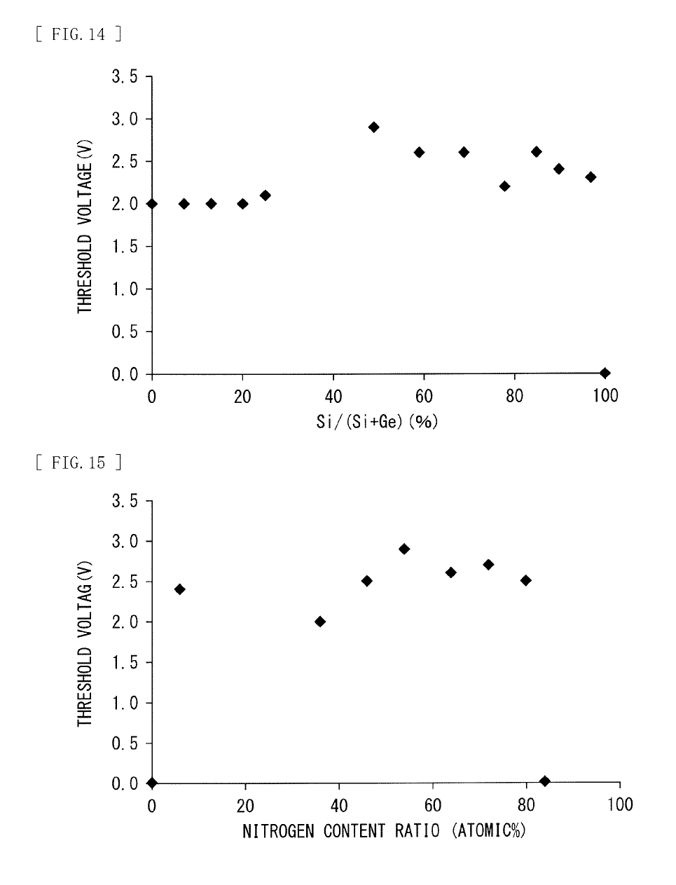

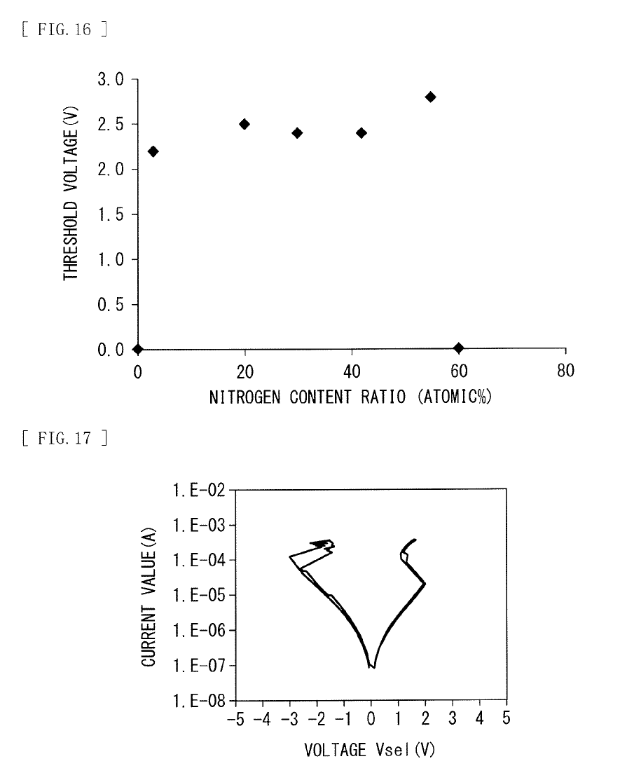

Next, in Experiment 3, a method similar to that of Experiment 1 was used except that the ratio of Si to Ge that configure the switch layer 30 is set such that Si to Ge was 6 to 4 (Si:Ge=6:4), and that flow rates and compositions of gases flowing at the time of film-formation were changed, to fabricate the following samples (Experimental Examples 3-1 to 3-9). The flow rates and the compositions of the gases in each of the samples were set such that: argon (Ar) gas flow rate was 75 sccm; and nitrogen (N₂) flow rates in the respective samples were 0, 2, 5, 7, 10, 15, 20, 25, and 30 sccm. Likewise, samples (Experimental Examples 3-10 to 3-16) were fabricated, by setting the ratio of Si to Ge that configure the switch layer 30 such that Si to Ge was 5 to 5 (Si:Ge=5:5), and the flow rates and the compositions of the gases in each of the samples were set such that: argon (Ar) gas flow rate was 75 sccm; and oxygen (O₂) flow rates in the respective samples were 0, 1, 2, 5, 10, 15, and 20 sccm. Tables 1 and 2 summarize respective measurements of N content and O content in these samples using an X-ray photoelectron spectroscopy (XPS). Further, these samples were subjected to the DC loop measurement similarly to Experiment 1 to examine a current change (resistance change) with respect to a voltage. FIG. 15 (SiGe—Nx) and FIG. 16 (SiGe—Ox) illustrate changes in the switching threshold voltages relative to the content of nitrogen (N) and the content of oxygen (O), respectively.

TABLE 1

| | Nitrogen (N₂) | XPS measurement |
|---|---|---|
| | Flow Rate | (%) |
| Experimental Example 3-1 | 0 | 0 |
| Experimental Example 3-2 | 2 | 3 |
| Experimental Example 3-3 | 5 | 18 |
| Experimental Example 3-4 | 7 | 23 |
| Experimental Example 3-5 | 10 | 27 |
| Experimental Example 3-6 | 15 | 32 |
| Experimental Example 3-7 | 20 | 36 |
| Experimental Example 3-8 | 25 | 40 |
| Experimental Example 3-9 | 30 | 42 |

TABLE 2

| | Nitrogen (N₂) | XPS measurement |
|---|---|---|
| | Flow Rate | (%) |
| Experimental Example 3-10 | 0 | 0 |
| Experimental Example 3-11 | 1 | 3 |
| Experimental Example 3-12 | 2 | 20 |
| Experimental Example 3-13 | 5 | 30 |
| Experimental Example 3-14 | 10 | 36 |
| Experimental Example 3-15 | 15 | 42 |
| Experimental Example 3-16 | 20 | 51 |

It is appreciated, from FIG. 15, that, within a nitrogen content range of equal to or higher than 3 atomic % to equal to or lower than 40 atomic %, there is the switching threshold voltage, and there are the switch characteristics and the negative resistance characteristics in which a current value is changed abruptly upon application of a voltage. Further, when the nitrogen content is at 0 atomic % or at 43 atomic %, there is no switching threshold voltage, and no switching characteristic is observed. Accordingly, it is appreciated that the nitrogen content that allows for obtainment of the negative resistance characteristics and the switch characteristics in the switch layer 30 made of SiGe—Nx may be preferably set to equal to or higher than 3 atomic % and equal to or lower than 40 atomic %. In contrast, it is appreciated, from FIG. 16, that, within an oxygen content range of equal to or higher than 3 atomic % to equal to or lower than 55 atomic %, there is the switching threshold voltage, and there are the switch characteristics and the negative resistance characteristics in which a current value is changed abruptly upon application of a voltage. Further, when the oxygen content is at 0 atomic % or at 60 atomic %, there is no switching threshold voltage, and no switching characteristic is observed. Accordingly, it is appreciated that the oxygen content that allows for obtainment of the negative resistance characteristics and the switch characteristics in the switch layer 30 made of SiGe—Ox may be preferably set to equal to or higher than 3 atomic % and equal to or lower than 55 atomic %.

### (Experiment 4)

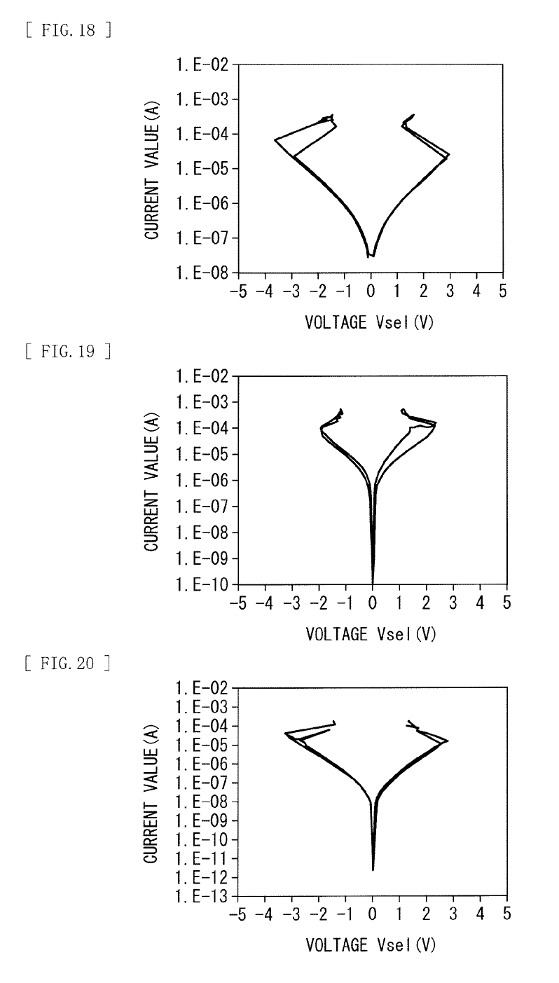

Next, in Experiment 4, a method similar to that of the above-described Experiment 1 was used to form the switch layer 30 made of GeNx containing carbon (C) or boron (B) as an additive element or both of them while allowing an argon gas or a nitrogen gas to flow into a film-forming chamber, thus fabricating samples (Experimental Examples 4-1 to 4-3). Likewise, an oxygen gas instead of a nitrogen gas was allowed to flow into the film-forming chamber to form the switch layer 30 made of GeOx containing carbon (C) or boron (B) as an additive element or both of them, thus fabricating a sample (Experimental Example 4-4). Further, the argon gas and the nitrogen gas were allowed to flow into the film-forming chamber to fabricate a sample (Experimental Example 4-5) using silicon (Si) and carbon (C) as an additive element and a sample (Experimental Example 4-6) using silicon (Si) and boron (B) as an additive element. Composition ratios of the switch layer 30 in respective samples are shown below. It is to be noted that each thickness of the switch layer 30 and the upper electrode 20 in each of the samples is 30 nm. These samples were subjected to the DC loop measurement similarly to Experiment 1 to examine a current change (resistance change) with respect to a voltage. FIGS. 17 to 20 illustrate respective I-V characteristics in Experimental Examples 4-1, 4-3, 4-5, and 4-6, and Table 3 summarizes respective switching threshold voltages in the samples.

### (Experimental Example 4-1) TiN/C20-Ge80-Nx/W

### (Experimental Example 4-2) TiN/B25-Ge85-Nx/W

### (Experimental Example 4-3) TiN/B56-C14-Ge30-Nx/W

### (Experimental Example 4-4) TiN/B56-C14-Ge30-Ox/W

### (Experimental Example 4-5) TiN/Si20-C20-Ge60-Nx/W

### (Experimental Example 4-6) TiN/B5-Si47.5-Ge47.5-Nx/W

TABLE 3

| | Switching Threshold |
|---|---|
| | Voltage (V) |
| Experimental Example 4-1 | 2.1 |
| Experimental Example 4-2 | 2.0 |
| Experimental Example 4-3 | 3.0 |
| Experimental Example 4-4 | 2.4 |
| Experimental Example 4-5 | 2.5 |
| Experimental Example 4-6 | 2.8 |

In comparison with the I-V characteristics of Experimental Example 1-1 in Experiment 1, the use of carbon (C) as an additive element lowered a current value in the switch layer 30 during an OFF state, making the difference definite with respect to the current value beyond the switching threshold voltage. Further, the negative resistance characteristics were made to be definite, as well. It is appreciated that, when comparing Experimental Example 4-1 with Experimental Example 4-3, the use of boron as an additive element further lowered a current value during the OFF state, thus further increasing the difference with respect to the current value beyond the switching threshold voltage. In other words, it is appreciated that the use of not only silicon used in Experiment 2 but also boron or carbon as the additive element to be used for the switch layer 30 makes it possible to enhance the switch characteristics of the switch layer 30.

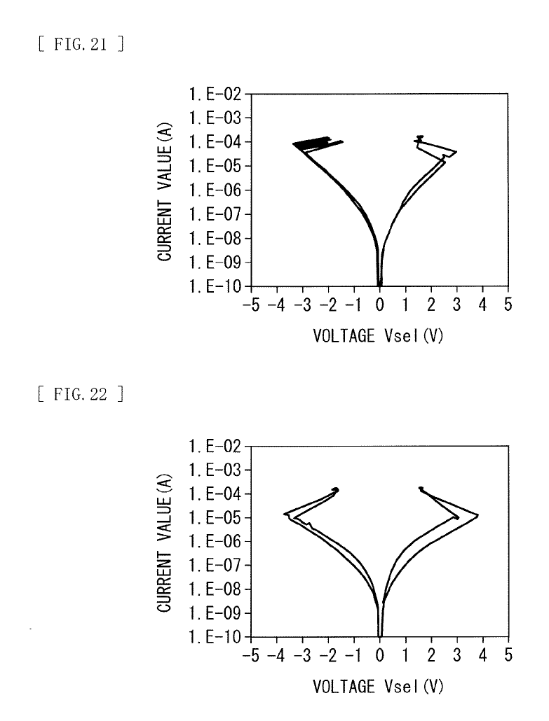

It is appreciated, from FIGS. 20 and 21, that the use of a mixture of two or more of silicon, boron, and carbon as the additive element also makes it possible to enhance the negative resistance characteristics and the switch characteristics. It is appreciated from the above that, by using Ge—Nx and Ge-Ox each configuring the switch layer of the present disclosure in combination with one of or two or more of silicon, boron, and carbon, as the additive element, it becomes possible to further enhance the switch characteristics such as reducing a leak current during an OFF state.

It is to be noted that silicon and carbon are in the same group and may have the same valence, and thus are considered to have similar properties. It is presumed that the combination of carbon, germanium, and nitrogen within the same range as silicon, germanium, and nitrogen achieves an effect similar to that of the combination of silicon, germanium, and nitrogen. It is contemplated from the above that preferable percentage of carbon to be added to the switch layer 30 for obtainment of the switch characteristics may be such that germanium percentage may be 3% to 100% both inclusive relative to germanium and carbon which account for 100%, in the same manner as silicon. It is contemplated that more preferable germanium percentage may be 10% to 93% both inclusive.

Further, boron has a valence of 3, and thus it is presumed that even a larger addition ratio of boron than silicon or carbon relative to germanium enables characteristics-enhancing effect to be obtained. In the case of the addition of boron, boron substitutes a portion or all of silicon or carbon for the above-described composition range of silicon (or carbon). In this case, when one silicon (or carbon) is substituted, it follows that four thirds of boron is substituted. Accordingly, in the case of a combination of boron, germanium, and nitrogen, a germanium percentage of 2% to 100% both inclusive enables the switch characteristics to be obtained. It is contemplated that more preferable germanium percentage may be 8% to 91% both inclusive.

Moreover, because each of the additive elements of silicon, carbon, and boron have an effect in enhancement of the characteristics, a combination of two or more of these elements together with germanium, nitrogen or oxygen also allows for obtainment of the characteristics-enhancing effect owing to the additive elements. Taking into consideration the percentage of germanium with respect to each of the additive elements, a germanium percentage of at least 3% or higher as a ratio of germanium to elements other than nitrogen or oxygen allows for the switch characteristics. It is presumed that a preferable germanium percentage of 10% to 91% both inclusive may clearly demonstrate the characteristics-enhancing effect owing to the additive elements.

### (Experiment 5)

First, as Experimental Example 5-1, the lower electrode 10 made of TiN was cleaned by means of reverse sputtering. Next, the switch layer 30A made of Ge—Nx having a film thickness of 10 nm was formed on TiN by means of reactive sputtering while allowing nitrogen to flow into a film-forming chamber, following which an SiNx film having a film thickness of 5 nm was formed to serve as the high resistive layer 70. Further, the switch layer 30A made of Ge—Nx having a film thickness of 10 nm was formed on the high resistive layer 70, following which tungsten (W) having a film thickness of 30 nm was formed to serve as the upper electrode 20. Furthermore, as Experimental Example 5-2, the lower electrode 10 made of TiN was cleaned by means of reverse sputtering, and thereafter an SiNx film having a film thickness of 10 nm was formed on Tin to provide the high resistive layer 70. Next, the switch layer 30A made of Ge—Nx having a film thickness of 30 nm was formed by means of reactive sputtering while allowing argon (Ar) and one of nitrogen (N) and oxygen (O) to flow into a film-forming chamber. Thereafter, the high resistive layer 70B was further formed, following which tungsten (W) having a film thickness of 30 nm was provided to serve as the upper electrode 20. A method similar to that of the above-described Experiment 1 was used to fabricate the switch device 3 as described below. Composition ratios of the respective layers in Experimental Examples 5-1 and 5-2 are shown below in the order of “lower electrode/switch layer/high resistive layer/switch layer/upper electrode” (Experimental Example 5-1) and in the order of “lower electrode/high resistive layer/switch layer/high resistive layer/upper electrode” (Experimental Example 5-2). Further, the I-V characteristics in Experimental Examples 5-1 and 5-2 are illustrated in FIGS. 21 and 22.

(Experimental Example 5-1) TiN/Si50-Ge50-Nx (10 nm)/SiNx (5 nm)/Si50-Ge50-Nx (10 mn)/W (30 nm)
(Experimental Example 5-2) TiN/SiNx (5 nm)/Si50-Ge50-Nx (10 mn)/SiNx (5 nm)/W (30 nm)

As it is appreciated from FIGS. 21 and 22, providing the high resistive layer 70 in addition to the switch layer 30 between the lower electrode 10 and the upper electrode 20 also allows the negative resistance characteristics and the switch characteristics as well as the switch threshold voltage to be present.

Although description has been given of the present disclosure, referring to embodiment, modification examples, and examples, the disclosure is by no means limited to the foregoing embodiment, modification examples, and examples, and various modifications are possible.

It is to be noted that the effects described in the foregoing embodiment, modification examples, and examples are not necessarily limitative, and may be any effects described in the present disclosure.

It is to be noted that the technology may also have the following configurations.

(1)

A switch device including:

a first electrode;

a second electrode disposed to face the first electrode; and

a switch layer provided between the first electrode and the second electrode, the switch layer containing an amorphous material made of at least germanium (Ge) and one of nitrogen (N) and oxygen (O).

(2)

The switch device according to (1), wherein the switch layer contains, as an additive element, one or more of boron (B), carbon (C), and silicon (Si).

(3)

The switch device according to (1) or (2), wherein the switch layer contains nitrogen (N) at equal to or higher than 3 atomic % and at equal to or lower than 40 atomic %.

(4)

The switch device according to any one of (1) to (3), wherein the switch layer contains oxygen (O) at equal to or higher than 3 atomic % and at equal to or lower than 55 atomic %.

(5)

The switch device according to any one of (2) to (4), wherein the switch layer contains germanium (Ge) at a content of equal to or higher than 3% relative to a content of silicon (Si).

(6)

The switch device according to any one of (2) to (4), wherein the switch layer contains germanium (Ge) at a content of equal to or higher than 10% and equal to or lower than 93% relative to a content of the additive element.

(7)

The switch device according to any one of (1) to (6), wherein the switch layer has a film thickness of equal to or less than 50 nm.

(8)

The switch device according to any one of (1) to (7), wherein

the switch layer is changed to be in a low resistance state by setting an applied voltage to equal to or higher than a predetermined threshold voltage, and

the switch layer is again changed to be in a high resistance state by decreasing the applied voltage to equal to or lower than the threshold voltage.

(9)

The switch device according to any one of (1) to (8), further including a high resistive layer provided between the first electrode and the second electrode, the high resistive layer containing an oxide or a nitride of one of a metal element and a non-metal element.

(10)

The switch device according to (9), wherein the high resistive layer is provided on one or both of surfaces, of the switch layer, which are located on side of the first electrode and on side of the second electrode.

(11)

A storage unit provided with a plurality of memory cells, each of the plurality of memory cells including a storage device, and a switch device coupled to the storage device, the switch device including:

a first electrode;

a second electrode disposed to face the first electrode; and

a switch layer provided between the first electrode and the second electrode, the switch layer containing an amorphous material made of at least germanium (Ge) and one of nitrogen (N) and oxygen (O).

(12)

The storage unit according to (11), wherein the storage device includes a storage layer provided between the first electrode and the second electrode of the switch device.

(13)

The storage unit according to (12), wherein the storage layer and the switch layer are stacked between the first electrode and the second electrode, with a third electrode provided between the storage layer and the switch layer.

(14)

The storage unit according to (12) or (13), wherein the storage layer includes an ion source layer and a resistance-change layer, the ion source layer containing one or more of chalcogen elements selected from tellurium (Te), sulfur (S), and selenium (Se).

(15)

The storage unit according to any one of (11) to (14), further including a plurality of row lines and a plurality of column lines, wherein the memory cells are disposed near respective intersection regions of the plurality of row lines and the plurality of column lines.

(16)

The storage unit according to any one of (12) to (15), wherein the storage layer includes any of a resistance-change layer made of a transition metal oxide, a phase-change memory layer, and a magnetoresistive random access memory layer.

This application is based upon and claims the benefit of priority of the Japanese Patent Application No. 2014-201722 filed with the Japan Patent Office on Sep. 30, 2014, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A switch device comprising:
a first electrode;
a second electrode disposed to face the first electrode; and
a switch layer provided between the first electrode and the second electrode, the switch layer containing an amorphous material made of at least germanium (Ge) and one of nitrogen (N) and oxygen (O).

2. The switch device according to claim 1, wherein the switch layer contains, as an additive element, one or more of boron (B), carbon (C), and silicon (Si).

3. The switch device according to claim 1, wherein the switch layer contains nitrogen (N) at equal to or higher than 3 atomic % and at equal to or lower than 40 atomic %.

4. The switch device according to claim 1, wherein the switch layer contains oxygen (O) at equal to or higher than 3 atomic % and at equal to or lower than 55 atomic %.

5. The switch device according to claim 2, wherein the switch layer contains germanium (Ge) at a content of equal to or higher than 3% relative to a content of silicon (Si).

6. The switch device according to claim 2, wherein the switch layer contains germanium (Ge) at a content of equal to or higher than 10% and equal to or lower than 93% relative to a content of the additive element.

7. The switch device according to claim 1, wherein the switch layer has a film thickness of equal to or less than 50 nm.

8. The switch device according to claim 1, wherein
the switch layer is changed to be in a low resistance state by setting an applied voltage to equal to or higher than a predetermined threshold voltage, and
the switch layer is again changed to be in a high resistance state by decreasing the applied voltage to equal to or lower than the threshold voltage.

9. The switch device according to claim 1, further comprising a high resistive layer provided between the first electrode and the second electrode, the high resistive layer containing an oxide or a nitride of one of a metal element and a non-metal element.

10. The switch device according to claim 9, wherein the high resistive layer is provided on one or both of surfaces, of the switch layer, which are located on side of the first electrode and on side of the second electrode.

11. A storage unit provided with a plurality of memory cells, each of the plurality of memory cells including a storage device, and a switch device coupled to the storage device, the switch device comprising:
a first electrode;
a second electrode disposed to face the first electrode; and
a switch layer provided between the first electrode and the second electrode, the switch layer containing an amorphous material made of at least germanium (Ge) and one of nitrogen (N) and oxygen (O).

12. The storage unit according to claim 11, wherein the storage device includes a storage layer provided between the first electrode and the second electrode of the switch device.

13. The storage unit according to claim 12, wherein the storage layer and the switch layer are stacked between the first electrode and the second electrode, with a third electrode provided between the storage layer and the switch layer.

14. The storage unit according to claim 12, wherein the storage layer includes an ion source layer and a resistance-change layer, the ion source layer containing one or more of chalcogen elements selected from tellurium (Te), sulfur (S), and selenium (Se).

15. The storage unit according to claim 11, further comprising a plurality of row lines and a plurality of column lines, wherein the memory cells are disposed near respective intersection regions of the plurality of row lines and the plurality of column lines.

16. The storage unit according to claim 12, wherein the storage layer comprises any of a resistance-change layer made of a transition metal oxide, a phase-change memory layer, and a magnetoresistive random access memory layer.
